(19) United States
(12) Patent Application Publication
(10) Pub. No.: US 2025/0271758 A1
(43) Pub. Date: Aug. 28, 2025

(54) PHOTOSENSITIVE RESIN COMPOSITION, PHOTOSENSITIVE ELEMENT, PRINTED WIRING BOARD, AND METHOD FOR PRODUCING PRINTED WIRING BOARD

(71) Applicant: Resonac Corporation, Minato-ku, Tokyo (JP)

(72) Inventors: Akihiro NAKAMURA, Minato-ku, Tokyo (JP); Naomitsu KOMORI, Minato-ku, Tokyo (JP); Shuji NOMOTO, Minato-ku, Tokyo (JP); Yuta DAIJIMA, Minato-ku, Tokyo (JP)

(21) Appl. No.: 18/858,051

(22) PCT Filed: Apr. 27, 2023
(86) PCT No.: PCT/JP2023/016740

§ 371 Date: Oct. 18, 2024

(30) Foreign Application Priority Data
May 6, 2022 (JP) 2022-076612

(51) Int. Cl. G03F 7/033; G03F 7/031; G03F 7/075; G03F 7/16; G03F 7/34

(52) U.S. Cl. CPC G03F 7/033; G03F 7/031; G03F 7/0751; G03F 7/0755; G03F 7/168; G03F 7/343

(57) ABSTRACT

An aspect of the present disclosure relates to a photosensitive resin composition containing (A) an acid-modified vinyl group-containing resin, (B) a thermosetting resin, (C) a photopolymerization initiator, (D) a photopolymerizable compound, and (E) an elastomer, in which (B) the thermosetting resin includes a bisphenol type epoxy compound having an average molecular weight of 360 or less and (E) the elastomer includes an acrylic elastomer.

### TECHNICAL FIELD

The present disclosure relates to a photosensitive resin composition, a photosensitive element, a printed wiring board, and a method for producing a printed wiring board.

### BACKGROUND ART

In the field of printed wiring boards, a permanent resist is formed on a printed wiring board. A permanent resist has a role of preventing corrosion of the conductor layers or maintaining electric insulation between the conductor layers when the printed wiring board is in use. In recent years, a permanent resist also has a role as a solder resist film that prevents solder from adhering to an unnecessary portion of the conductor layer of a printed wiring board in a process in which a semiconductor element is mounted on a printed wiring board via solder by flip chip mounting, wire bonding or the like as well.

Hitherto, permanent resists have been prepared by a screen printing method using a thermosetting resin composition or a photographic method using a photosensitive resin composition. For example, in flexible wiring boards using mounting methods such as FC (flip chip), TAB (tape automated bonding), and COF (chip on film), a thermosetting resin paste is screen printed except for the parts such as IC chips, electronic components, or LCD (liquid crystal display) panels and connecting wiring patterns, and then thermally cured to form a permanent resist (for example, see Patent Literature 1).

In semiconductor package substrates such as BGA (ball grid array) and CSP (chip size package) that are mounted on electronic components, it is necessary to remove the permanent resist from the joining portions (1) in order to flip-chip mount a semiconductor element on a semiconductor package substrate via solder, (2) in order to join a semiconductor element to a semiconductor package substrate by wire bonding, or (3) in order to join a semiconductor package substrate to a motherboard substrate by soldering. For image formation of permanent resist, a photographic method is used in which a photosensitive resin composition is applied, dried, and then cured by being selectively irradiated with actinic light such as ultraviolet light, and only the unirradiated portions are removed by development to form an image. A photographic method is suitable for mass production because of its favorable working properties and is thus widely used in the electronic materials industry for image formation of photosensitive materials (for example, see Patent Literature 2).

### CITATION LIST

### Patent Literature

Patent Literature 1: JP 2003-198105 A
Patent Literature 2: JP 2011-133851 A

### SUMMARY OF INVENTION

### Technical Problem

In response to the increase in density of printed wiring boards, permanent resists (solder resists) are also required to exhibit higher performance. In particular, the demands for fine pattern formation, heat resistance, and thermal shock resistance have increased year by year, and it is important to achieve all of these properties at high degrees.

An object of the present disclosure is to provide a photosensitive resin composition that exhibits excellent resolution and pattern formability and can form a permanent resist excellent in heat resistance and thermal shock resistance, a photosensitive element and a printed wiring board each obtained using the photosensitive resin composition, and a method for producing a printed wiring board.

### Solution to Problem

An aspect of the present disclosure relates to a photosensitive resin composition containing (A) an acid-modified vinyl group-containing resin, (B) a thermosetting resin, (C) a photopolymerization initiator, (D) a photopolymerizable compound, and (E) an elastomer, in which (B) the thermosetting resin includes a bisphenol type epoxy compound having an average molecular weight of 360 or less and (E) the elastomer includes an acrylic elastomer.

Another aspect of the present disclosure relates to a photosensitive element including a support film and a photosensitive layer formed on the support film, in which the photosensitive layer contains the photosensitive resin composition described above.

Another aspect of the present disclosure relates to a printed wiring board including a permanent resist containing a cured product of the photosensitive resin composition described above.

Another aspect of the present disclosure relates to a method for producing a printed wiring board, which includes a step of forming a photosensitive layer on a substrate using the photosensitive resin composition or photosensitive element described above, a step of exposing and developing the photosensitive layer to form a resist pattern; and a step of curing the resist pattern to form a permanent resist.

### Advantageous Effects of Invention

According to the present invention, it is possible to provide a photosensitive resin composition that exhibits excellent resolution and pattern formability and can form a permanent resist excellent in heat resistance and thermal shock resistance, a photosensitive element and a printed wiring board each obtained using the photosensitive resin composition, and a method for producing a printed wiring board.

### BRIEF DESCRIPTION OF DRAWINGS

FIG. 1 is a cross-sectional view schematically illustrating a photosensitive element according to the present embodiment.

### DESCRIPTION OF EMBODIMENTS

An aspect of the present disclosure relates to the following photosensitive resin composition, photosensitive element, printed wiring board, and method for producing a printed wiring board.

[1] A photosensitive resin composition containing: (A) an acid-modified vinyl group-containing resin; (B) a thermosetting resin; (C) a photopolymerization initiator; (D) a photopolymerizable compound; and (E) an elastomer, in which (B) the thermosetting resin includes a bisphenol type epoxy compound having an average molecular weight of 360 or less, and (E) the elastomer includes an acrylic elastomer.

[2] The photosensitive resin composition according to [1], in which a content of the thermosetting resin is 5% to 25% by mass based on a total solid amount in the photosensitive resin composition.

[3] The photosensitive resin composition according to [1] or [2], in which the acrylic elastomer has a carboxy group.

[4] The photosensitive resin composition according to [3], in which the acrylic elastomer further has a n-butyl group.

[5] The photosensitive resin composition according to any one of [1] to [4], in which the acrylic elastomer has a weight average molecular weight of 5000 to 20000.

[6] The photosensitive resin composition according to any one of [1] to [5], further containing (I) a silane coupling agent.

[7] The photosensitive resin composition according to any one of [1] to [6], further containing (F) an inorganic filler.

[8]A photosensitive element including: a support film; and a photosensitive layer formed on the support film, in which the photosensitive layer contains the photosensitive resin composition according to any one of [1] to [7].

[9]A printed wiring board including a permanent resist containing a cured product of the photosensitive resin composition according to any one of [1] to [7].

[10]A method for producing a printed wiring board, the method including: a step of forming a photosensitive layer on a substrate using the photosensitive resin composition according to any one of [1] to [7]; a step of exposing and developing the photosensitive layer to form a resist pattern; and a step of curing the resist pattern to form a permanent resist.

[11]A method for producing a printed wiring board, the method including: a step of forming a photosensitive layer on a substrate using the photosensitive element according to [8]; a step of exposing and developing the photosensitive layer to form a resist pattern; and a step of curing the resist pattern to form a permanent resist.

Hereinafter, the present disclosure will be described in detail. In this specification, the term “step” includes not only an independent step, but also a step that cannot be clearly distinguished from another step as long as the intended action of the step is achieved. The term “layer” encompasses a structure having a shape formed on a part of a surface as well as a structure having a shape formed on the entire surface when observed in plan view. The numerical range indicated using “to” indicates a range that includes the numerical values before and after “to” as the minimum and maximum values, respectively. In a numerical range described in stages in this specification, the upper limit or lower limit of a numerical range at a certain stage may be replaced with the upper limit or lower limit of a numerical range at another stage. In a numerical range described in this specification, the upper limit or lower limit of the numerical range may be replaced with a value shown in Examples.

In this specification, in a case of referring to the amount of each component in a composition, when a plurality of substances corresponding to each component are present in the composition, the amount means the total amount of the plurality of substances present in the composition, unless otherwise specified.

In this specification, the term “(meth)acrylate” refers to at least either of “acrylate” or “methacrylate” corresponding thereto, and the same applies to other similar expressions such as (meth)acrylic acid and (meth)acryloyl. In this specification, the term “solids” refers to non-volatile components excluding volatile substances (water, solvent and the like) contained in the photosensitive resin composition, and includes components that are liquid, syrup-like, or wax-like at room temperature (around 25° C.).

### [Photosensitive Resin Composition]

The photosensitive resin composition according to the present embodiment contains (A) an acid-modified vinyl group-containing resin, (B) a thermosetting resin, (C) a photopolymerization initiator, (D) a photopolymerizable compound, and (E) an elastomer as essential components. The photosensitive resin composition according to the present embodiment is a negative photosensitive resin composition, and a cured film of the photosensitive resin composition can be suitably used as a permanent resist. Hereinafter, each component used in the photosensitive resin composition of the present embodiment will be described in more detail.

### (Component (a): Acid-Modified Vinyl Group-Containing Resin)

The photosensitive resin composition according to the present embodiment contains an acid-modified vinyl group-containing resin as a component (A). The acid-modified vinyl group-containing resin is not particularly limited as long as it has a vinyl bond, which is a photopolymerizable ethylenically unsaturated bond, and an alkali-soluble acidic group.

Examples of the group having an ethylenically unsaturated bond, which the component (A) has, include a vinyl group, an allyl group, a propargyl group, a butenyl group, an ethynyl group, a phenylethynyl group, a maleimide group, a nadimide group, and a (meth)acryloyl group. Among these, a (meth)acryloyl group is preferred from the viewpoints of reactivity and resolution. Examples of the acidic group, which the component (A) has, include a carboxy group, a sulfo group, and a phenolic hydroxyl group. Among these, a carboxy group is preferred from the viewpoint of resolution.

The component (A) is preferably an acid-modified vinyl group-containing epoxy derivative obtained by reacting (a) an epoxy resin (hereinafter, sometimes referred to as “component (a)”) with (b) an ethylenically unsaturated group-containing organic acid (hereinafter, sometimes referred to as “component (b)”) to obtain a resin (A′) and reacting the resin (A′) with (c) a saturated or unsaturated group-containing polybasic acid anhydride (hereinafter, sometimes referred to as “component (c)”).

Examples of the acid-modified vinyl group-containing epoxy derivative include acid-modified epoxy (meth)acrylate. The acid-modified epoxy (meth)acrylate is a resin obtained by subjecting an epoxy (meth)acrylate, which is a reaction product of the component (a) with the component (b), to acid modification with the component (c). As the acid-modified epoxy (meth)acrylate, for example, an addition reaction product can be used in which a saturated or unsaturated polybasic acid anhydride is added to an esterification product obtained by reacting an epoxy resin with a vinyl group-containing monocarboxylic acid.

Examples of the component (A) include an acid-modified vinyl group-containing resin (A1) (hereinafter, sometimes referred to as “component (A1)”) obtained by using a bisphenol novolac type epoxy resin (a1) (hereinafter, sometimes referred to as “epoxy resin (a1)”) as the component (a) and an acid-modified vinyl group-containing resin (A2) (hereinafter, sometimes referred to as “component (A2)”) obtained by using an epoxy resin (a2) other than the epoxy resin (a1) (hereinafter, sometimes referred to as “epoxy resin (a2)”) as the component (a).

Examples of the epoxy resin (a1) include epoxy resins having a structural unit represented by the following Formula (I) or (II).

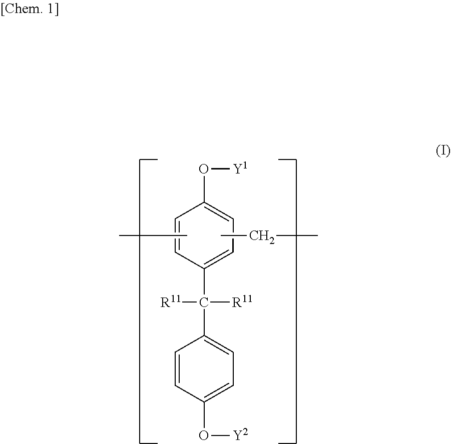

In Formula (I), R¹¹ represents a hydrogen atom or a methyl group, and a plurality of R¹¹'s may be the same as or different from each other. Y¹ and Y² each independently represent a hydrogen atom or a glycidyl group, provided that at least either of Y¹ or Y² is a glycidyl group. R¹¹ is preferably a hydrogen atom from the viewpoint of suppressing the occurrence of undercut and improving the linearity of the resist pattern contour and resolution, and Y¹ and Y² are preferably a glycidyl group from the viewpoint of further improving the thermal shock resistance.

The number of structural units represented by Formula (I) in the epoxy resin (a1) is 1 or more, and may be 10 to 100, 12 to 80, or 15 to 70. When the number of structural units is in the above range, the linearity of the resist pattern contour, close contact properties to a copper substrate, heat resistance, and electric insulation are likely to be improved. Here, the number of structural units of a structural unit indicates an integer value in a single molecule, and indicates a rational number that is an average value in an aggregate of plural kinds of molecules. The same applies to the number of structural units of a structural unit hereinafter.

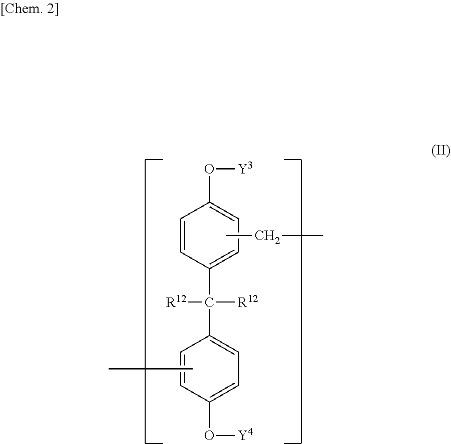

In Formula (II), R¹² represents a hydrogen atom or a methyl group, and a plurality of R¹²'s may be the same as or different from each other. Y³ and Y⁴ each independently represent a hydrogen atom or a glycidyl group, provided that at least either of Y³ or Y⁴ is a glycidyl group. R¹² is preferably a hydrogen atom from the viewpoint of suppressing the occurrence of undercut and improving the linearity of the resist pattern contour and resolution, and Y³ and Y⁴ are preferably a glycidyl group from the viewpoint of further improving the thermal shock resistance.

The number of structural units represented by Formula (II) in the epoxy resin (a1) is 1 or more, and may be 10 to 100, 12 to 80, or 15 to 70. When the number of structural units is in the above range, the linearity of the resist pattern contour, close contact properties to a copper substrate, and heat resistance are likely to be improved.

An epoxy resin represented by Formula (II) where R¹² is a hydrogen atom and Y³ and Y⁴ are a glycidyl group is commercially available as EXA-7376 series (trade name, manufactured by DIC Corporation), and an epoxy resin represented by Formula (II) where R¹² is a methyl group and Y³ and Y⁴ are a glycidyl group is commercially available as EPON SU8 series (trade name, manufactured by Mitsubishi Chemical Corporation).

The epoxy resin (a2) is not particularly limited as long as it is an epoxy resin different from the epoxy resin (a1), but is preferably at least one selected from the group consisting of a novolac type epoxy resin, a bisphenol A type epoxy resin, a bisphenol F type epoxy resin, a triphenolmethane type epoxy resin, and a biphenyl type epoxy resin from the viewpoint of suppressing the occurrence of undercut and improving the linearity of the resist pattern contour, close contact properties to a copper substrate, and resolution.

Examples of the novolac type epoxy resin include epoxy resins having a structural unit represented by the following Formula (III). Examples of the bisphenol A type epoxy resin or bisphenol F type epoxy resin include epoxy resins having a structural unit represented by the following Formula (IV). Examples of the triphenolmethane type epoxy resin include epoxy resins having a structural unit represented by the following Formula (V). Examples of the biphenyl type epoxy resin include epoxy resins having a structural unit represented by the following Formula (VI).

The epoxy resin (a2) is preferably a novolac type epoxy resin having a structural unit represented by the following Formula (III). Examples of the novolac type epoxy resin having such a structural unit include a novolac type epoxy resin represented by the following Formula (III′).

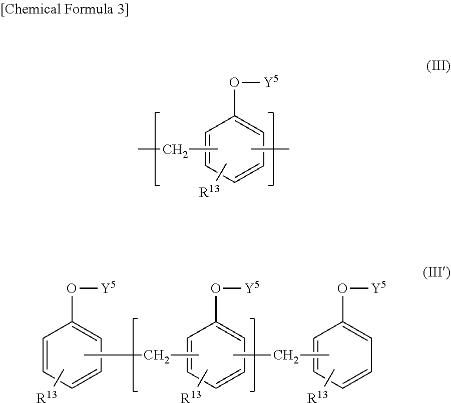

In Formulas (III) and (III′), R¹³ represents a hydrogen atom or a methyl group, and Y⁵ represents a hydrogen atom or a glycidyl group, provided that at least one Y⁵ is a glycidyl group. In Formula (III′), n₁ is a number of 1 or more, and a plurality of R¹³'s and a plurality of Y⁵'s may be the same as or different from each other, respectively. From the viewpoint of suppressing the occurrence of undercut and improving the linearity of the resist pattern contour and resolution, R¹³ is preferably a hydrogen atom.

In Formula (III′), the molar ratio of Y⁵ that is a hydrogen atom to Y⁵ that is a glycidyl group may be 0/100 to 30/70 or 0/100 to 10/90 from the viewpoint of suppressing the occurrence of undercut and improving the linearity of the resist pattern contour and resolution. n₁ is 1 or more, but may be 10 to 200, 20 to 150, or 30 to 100. When n₁ is in the above range, the linearity of the resist pattern contour, close contact properties to a copper substrate, and heat resistance are likely to be improved.

Examples of the novolac type epoxy resin represented by Formula (III′) include a phenol novolac type epoxy resin and a cresol novolac type epoxy resin. These novolac type epoxy resins can be obtained by, for example, reacting a phenol novolac resin or a cresol novolac resin with epichlorohydrin by a known method.

As the phenol novolac type epoxy resin or cresol novolac type epoxy resin represented by Formula (III′), for example, YDCN-701, YDCN-702, YDCN-703, YDCN-704, YDCN-704L, YDPN-638, and YDPN-602 (all trade names, manufactured by NIPPON STEEL Chemical & Material Co., Ltd.), DEN-431 and DEN-439 (all trade names, manufactured by The Dow Chemical Company), EOCN-120, EOCN-102S, EOCN-103S, EOCN-104S, EOCN-1012, EOCN-1025, EOCN-1027, and BREN (all trade names, manufactured by Nippon Kayaku Co., Ltd.), EPN-1138, EPN-1235, and EPN-1299 (all trade names, manufactured by BASF), and N-730, N-770, N-865, N-665, N-673, VH-4150, and VH-4240 (all trade names, manufactured by DIC Corporation) are commercially available.

Preferred examples of the epoxy resin (a2) include a bisphenol A type epoxy resin or bisphenol F type epoxy resin having a structural unit represented by the following Formula (IV). Examples of the epoxy resin having such a structural unit include a bisphenol A type epoxy resin or bisphenol F type epoxy resin represented by the following Formula (IV′).

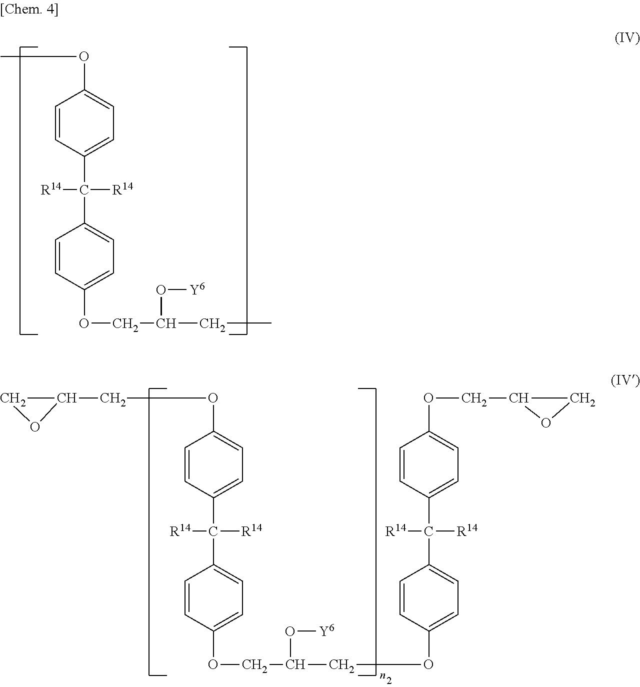

In Formulas (IV) and (IV′), R¹⁴ represents a hydrogen atom or a methyl group, and a plurality of R¹⁴'s may be the same as or different from each other, and Y⁶ represents a hydrogen atom or a glycidyl group. In Formula (IV′), n₂ represents a number of 1 or more, and when n₂ is 2 or more, a plurality of Y⁶'s may be the same as or different from each other, and at least one Y⁶ is a glycidyl group.

R¹⁴ is preferably a hydrogen atom from the viewpoint of suppressing the occurrence of undercut and improving the linearity of the resist pattern contour and resolution, and Y⁶ is preferably a glycidyl group from the viewpoint of further improving the thermal shock resistance. n₂ represents 1 or more, but may be 10 to 100, 12 to 80, or 15 to 60. When n₂ is in the above range, the linearity of the resist pattern contour, close contact properties to a copper substrate, and heat resistance are likely to be improved.

The bisphenol A type epoxy resin or bisphenol F type epoxy resin represented by Formula (IV) where Y⁶ is a glycidyl group can be obtained by, for example, reacting the hydroxyl group (—OY⁶) of a bisphenol A type epoxy resin or bisphenol F type epoxy resin represented by Formula (IV) where Y⁶ is a hydrogen atom with epichlorohydrin.

In order to promote the reaction of a hydroxyl group with epichlorohydrin, it is preferable to conduct the reaction in a polar organic solvent such as dimethylformamide, dimethylacetamide, or dimethyl sulfoxide at a reaction temperature of 50° C. to 120° C. in the presence of an alkali metal hydroxide. When the reaction temperature is in the above range, the reaction does not proceed too slow and side reactions can be suppressed.

As the bisphenol A type epoxy resin or bisphenol F type epoxy resin represented by Formula (IV′), for example, jER807, jER815, jER825, jER827, jER828, jER834, jER1001, jER1004, jER1007 and jER1009 (all trade names, manufactured by Mitsubishi Chemical Corporation), DER-330, DER-301, and DER-361 (all trade names, manufactured by The Dow Chemical Company), and YD-8125, YDF-170, YDF-175S, YDF-2001, YDF-2004, and YDF-8170 (all trade names, manufactured by NIPPON STEEL Chemical & Material Co., Ltd.) are commercially available.

Preferred examples of the epoxy resin (a2) include triphenolmethane type epoxy resins having a structural unit represented by the following Formula (V). Examples of the triphenolmethane type epoxy resins having such a structural unit include a triphenolmethane type epoxy resin represented by the following Formula (V′).

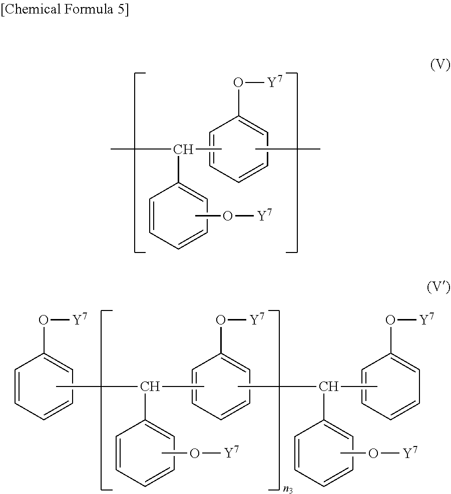

In Formulas (V) and (V′), Y⁷ represents a hydrogen atom or a glycidyl group, a plurality of Y⁷'s may be the same as or different from each other, and at least one Y⁷ is a glycidyl group. In Formula (V′), n₃ represents a number of 1 or more.

From the viewpoint of suppressing the occurrence of undercut and missing of the upper part and improving the linearity of the resist pattern contour and resolution, the molar ratio of Y⁷ that is a hydrogen atom to Y⁷ that is a glycidyl group in Y⁷'s may be 0/100 to 30/70. As can be seen from this molar ratio as well, at least one Y⁷ is a glycidyl group. n₃ is 1 or more, but may be 10 to 100, 12 to 80, or 15 to 70. When n₃ is in the above range, the linearity of the resist pattern contour, close contact properties to a copper substrate, and heat resistance are likely to be improved.

As the triphenolmethane type epoxy resin represented by Formula (V′), for example, FAE-2500, EPPN-501H, and EPPN-502H (all trade names, manufactured by Nippon Kayaku Co., Ltd.) are commercially available.

Preferred examples of the epoxy resin (a2) include biphenyl type epoxy resins having a structural unit represented by the following Formula (VI). Examples of the biphenyl type epoxy resins having such a structural unit include a biphenyl type epoxy resin represented by the following Formula (VI′).

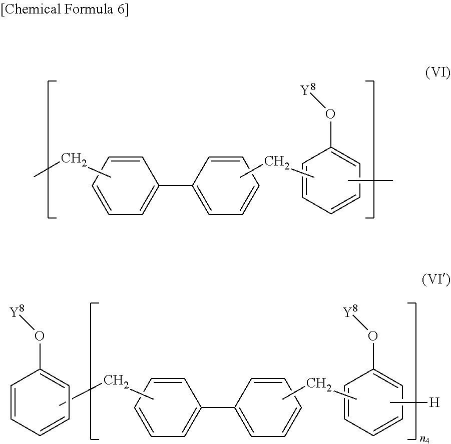

In Formulas (VI) and (VI′), Y⁸ represents a hydrogen atom or a glycidyl group, a plurality of Y's may be the same as or different from each other, and at least one Y⁸ is a glycidyl group. In Formula (VI′), n₄ represents a number of 1 or more.

As the biphenyl type epoxy resin represented by Formula (VI′), for example, NC-3000, NC-3000-L, NC-3000-H, NC-3000-FH-75M, NC-3100, and CER-3000-L (all trade names, manufactured by Nippon Kayaku Co., Ltd.) are commercially available.

The epoxy resin (a2) is preferably at least one selected from the group consisting of a novolac type epoxy resin having a structural unit represented by Formula (III), a bisphenol A type epoxy resin having a structural unit represented by Formula (IV), and a bisphenol F type epoxy resin having a structural unit represented by Formula (IV), and is more preferably a bisphenol F type epoxy resin having a structural unit represented by formula (IV).

From the viewpoint of further improving thermal shock resistance, warpage reduction, and resolution, the component (A1) obtained using a bisphenol novolac type epoxy resin having a structural unit represented by Formula (II) as the epoxy resin (a1) and the component (A2) obtained using a bisphenol A type epoxy resin or a bisphenol F type epoxy resin having a structural unit represented by Formula (IV) as the epoxy resin (a2) may be used in combination.

Examples of the component (b) include acrylic acid derivatives such as acrylic acid, a dimer of acrylic acid, methacrylic acid, β-furfuryl acrylic acid, β-styryl acrylic acid, cinnamic acid, crotonic acid, and α-cyanocinnamic acid; a half-ester compound which is a reaction product of a hydroxyl group-containing (meth)acrylate with a dibasic acid anhydride; a half-ester compound which is a reaction product of a vinyl group-containing monoglycidyl ether or vinyl group-containing monoglycidyl ester with a dibasic acid anhydride. The component (b) may be used singly or in combination of two or more kinds thereof.

The half-ester compound can be obtained by, for example, reacting a hydroxyl group-containing (meth)acrylate, vinyl group-containing monoglycidyl ether or vinyl group-containing monoglycidyl ester with a dibasic acid anhydride.

Examples of the hydroxyl group-containing (meth)acrylate, vinyl group-containing monoglycidyl ether, and vinyl group-containing monoglycidyl ester include hydroxyethyl (meth)acrylate, hydroxypropyl (meth)acrylate, hydroxybutyl (meth)acrylate, polyethylene glycol mono(meth)acrylate, trimethylolpropane di(meth)acrylate, pentaerythritol tri(meth)acrylate, dipentaerythritol penta(meth)acrylate, and glycidyl (meth)acrylate.

Examples of the dibasic acid anhydride include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride.

In the reaction of the component (a) with the component (b), the component (a) is reacted with the component (b) at a ratio so that the equivalent of the component (b) is preferably 0.6 to 1.05, more preferable 0.8 to 1.0 with respect to 1 equivalent of the epoxy group in the component (a). By conducting the reaction at such a ratio, the photosensitivity increases and the linearity of the resist pattern contour tends to be excellent.

The components (a) and (b) can be reacted in a state of being dissolved in an organic solvent. Examples of the organic solvent include ketones such as methyl ethyl ketone and cyclohexanone; aromatic hydrocarbons such as toluene, xylene, and tetramethylbenzene; glycol ethers such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; esters such as ethyl acetate, butyl acetate, butyl cellosolve acetate, and carbitol acetate; aliphatic hydrocarbons such as octane and decane; and petroleum-based solvents such as petroleum ether, petroleum naphtha, hydrogenated petroleum naphtha, and solvent naphtha. The organic solvents may be used singly or in combination of two or more kinds thereof.

A catalyst may be used to promote the reaction of the component (a) with the component (b). Examples of the catalyst include triethylamine, benzylmethylamine, methyltriethylammonium chloride, benzyltrimethylammonium chloride, benzyltrimethylammonium bromide, benzyltrimethylammonium iodide, and triphenylphosphine. The catalysts may be used singly or in combination of two or more kinds thereof.

The amount of the catalyst used may be 0.01 to 10 parts by mass, 0.05 to 2 parts by mass, or 0.1 to 1 part by mass with respect to 100 parts by mass of the total amount of the components (a) and (b) from the viewpoint of promoting the reaction of the component (a) with the component (b).

In the reaction of the component (a) with the component (b), a polymerization inhibitor may be used for the purpose of preventing polymerization during the reaction. Examples of the polymerization inhibitor include hydroquinone, methylhydroquinone, hydroquinone monomethyl ether, catechol, and pyrogallol. The polymerization inhibitors may be used singly or in combination of two or more kinds thereof.

The amount of the polymerization inhibitor used may be 0.01 to 1 part by mass, 0.02 to 0.8 parts by mass, or 0.04 to 0.5 parts by mass with respect to 100 parts by mass of the total amount of the components (a) and (b) from the viewpoint of improving stability.

The temperature for the reaction of the component (a) with the component (b) may be 60° C. to 150° C., 80° C. to 120° C., or 90° C. to 110° C. from the viewpoint of productivity.

The component (A′) obtained by reacting the component (a) with the component (b) has a hydroxyl group formed by a ring-opening addition reaction of the epoxy group in the component (a) with the carboxyl group in the component (b). By further reacting the component (A′) with the component (c), an acid-modified vinyl group-containing resin is obtained in which the hydroxyl groups in the component (A′) (including the hydroxyl groups originally present in the component (a)) and the acid anhydride groups in the component (c) are half-esterified.

Examples of the component (c) include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride. Among these, tetrahydrophthalic anhydride is preferred from the viewpoint of resolution. The component (c) may be used singly or in combination of two or more kinds thereof.

In the reaction of the component (A′) with the component (c), for example, by reacting the component (A′) with the component (c) so that the equivalent of the component (c) is 0.1 to 1.0 with respect to 1 equivalent of the hydroxyl group in the component (A′), the acid value of the component (A) can be adjusted.

The temperature for the reaction of the component (A′) with the component (c) may be 50° C. to 150° C., 60° C. to 120° C., or 70° C. to 100° C. from the viewpoint of productivity.

If necessary, a hydrogenated bisphenol A type epoxy resin may be used together in part as the component (a), and a styrene-maleic acid-based resin such as a hydroxyethyl (meth)acrylate-modified product of a styrene-maleic anhydride copolymer may be used together in part.

It is preferable that the component (A) includes a component (A1) from the viewpoints of suppressing the occurrence of undercut and further improving close contact properties to a copper substrate, thermal shock resistance, and resolution, and it is more preferable that the component (A) includes the component (A1) and a component (A2) particularly from the viewpoint of improving the close contact strength.

In a case where the component (A1) and the component (A2) are used in combination as the component (A), the mass ratio of (A1)/(A2) is not particularly limited but may be 20/80 to 90/10, 30/70 to 80/20, 40/60 to 75/25, or 50/50 to 70/30 from the viewpoint of improving the linearity of the resist pattern contour, resistance to electroless plating, and heat resistance.

The acid value of the component (A) is not particularly limited. From the viewpoint of improving the solubility of the unexposed portion in an aqueous alkaline solution, the acid value of the component (A) may be 30 mgKOH/g or more, 40 mgKOH/g or more, or 50 mgKOH/g or more. From the viewpoint of improving the electrical properties of the cured film, the acid value of the component (A) may be 150 mgKOH/g or less, 120 mgKOH/g or less, or 100 mgKOH/g or less.

The weight average molecular weight (Mw) of the component (A) is not particularly limited. From the viewpoint of improving the close contact properties of a cured film, the Mw of the component (A) may be 3000 or more, 4000 or more, or 5000 or more. From the viewpoint of improving the resolution of the photosensitive layer, the Mw of the component (A) may be 30000 or less, 25000 or less, or 18000 or less.

The Mw can be measured by gel permeation chromatography (GPC). With regard to the Mw, for example, measurement can be performed under the following GPC conditions and the value converted using the calibration curve of standard polystyrene can be taken as the Mw. For creation of the calibration curve, a five-sample set (“PStQuick MP-H” and “PStQuick B”, manufactured by Tosoh Corporation) can be used as standard polystyrene.
GPC system: High-speed GPC system “HCL-8320GPC” (manufactured by Tosoh Corporation)
Detector: Differential refractometer or UV detector (manufactured by Tosoh Corporation)
Column: TSKgel SuperMultipore HZ-H column (column length: 15 cm, column inner diameter: 4.6 mm) (manufactured by Tosoh Corporation)
Eluent: Tetrahydrofuran (THF)
Measurement temperature: 40° C.
Flow rate: 0.35 mL/min
Sample concentration: 10 mg/5 mL THF
Injection volume: 20 μL

The content of the component (A) in the photosensitive resin composition may be 20% to 70% by mass, 25% to 60% by mass, or 30% to 50% by mass based on the total solid amount in the photosensitive resin composition from the viewpoint of improving the heat resistance, electrical properties, and chemical resistance of the permanent resist.

### (Component (B): Thermosetting Resin)

The photosensitive resin composition according to the present embodiment contains a thermosetting resin as a component (B), and the component (B) includes a bisphenol type epoxy compound (hereinafter, sometimes referred to as “component (B1)”) having an average molecular weight of 360 or less. As the photosensitive resin composition according to the present embodiment contains the component (B1), the heat resistance and thermal shock resistance of the cured film (permanent resist) formed from the photosensitive resin composition can be improved while favorable resolution is maintained.

The component (B1) is an epoxy compound synthesized by a condensation reaction of a bisphenol compound with epichlorohydrin. Examples of the bisphenol compound include bisphenol A, bisphenol F, and bisphenol S. The component (B1) contains, as a main component, a diglycidyl ether having a bisphenol skeleton (diglycidyl ether represented by the following Formula (1)) in which 2 moles of epichlorohydrin are bonded to 1 mole of a bisphenol compound.

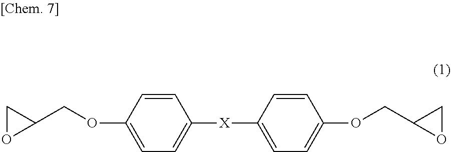

In Formula (1), X represents a methylene group (CH₂), an ethylene group (CH₂CH₂), an ethylidene group (CH(CH₃)), a 1-methylethylidene group (C(CH₃)₂), or a sulfo group. From the viewpoint of enhancing developability, X is preferably a methylene group or a 1-methylethylidene group.

A general bisphenol type epoxy compound includes a polymer (for example, an oligomer component such as a dimer or trimer) of a bisphenol compound and epichlorohydrin. In contrast, the component (B1) has a low content of oligomer component. The content of the diglycidyl ether represented by Formula (1) in the component (B1) may be 94% by mass or more, 96% by mass or more, or 98% by mass or more from the viewpoint of further improving developability and thermal shock resistance.

The average molecular weight of the component (B1) may be 310 to 360, 315 to 359, 320 to 358, 325 to 357, or 330 to 356 from the viewpoint of further improving heat resistance and thermal shock resistance. The average molecular weight can be calculated, for example, by the GPC method (see “Measurement of degree of polymerization of epoxy oligomers by GPC, NMR and the like”, Reports of the Central Customs Laboratory, No. 21, 1980, pp. 85-90)

From the viewpoint of further improving heat resistance and thermal shock resistance, the epoxy equivalent of the component (B1) may be 150 g/eq to 182 g/eq, 154 g/eq to 181 g/eq, 160 g/eq to 180 g/eq, 162 g/eq to 179 g/eq, or 166 g/eq to 178 g/eq. The epoxy equivalent can be measured in accordance with JIS K 7236.

The component (B) may include a thermosetting resin other than the component (B1). Examples of the other thermosetting resin include an epoxy resin not having a bisphenol skeleton, a phenolic resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin. Among these, from the viewpoint of further improving the heat resistance of the cured film, an epoxy resin not having a bisphenol skeleton is preferred. Examples of the epoxy resin not having a bisphenol skeleton include a novolac type epoxy resin, a dicyclopentadiene type epoxy resin, a hydrogenated bisphenol A type epoxy resin, a biphenyl type epoxy resin, a hydantoin type epoxy resin, a triglycidyl isocyanurate, and a bixylenol type epoxy resin.

The content of the component (B1) in the component (B) may be 30% by mass or more, 50% by mass or more, or 60% by mass or more based on the total amount of the component (B). When this content is 30% by mass or more, superior thermal shock resistance tends to be obtained.

The content of the component (B) in the photosensitive resin composition may be 2% to 30% by mass, 5% to 25% by mass, 8% to 20% by mass, or 10% to 18% by mass based on the total solid amount in the photosensitive resin composition. When the content of the component (B) is in the above range, the close contact properties and heat resistance of the cured film to be formed can be further improved while favorable developability is maintained.

### (Component (C): Photopolymerization Initiator)

The photopolymerization initiator that is component (C) is not particularly limited as long as it can polymerize the component (A) and the component (D). The component (C) may be used singly or in combination of two or more kinds thereof.

Examples of the component (C) include benzoin compounds such as benzoin, benzoin methyl ether, and benzoin isopropyl ether; acetophenone compounds such as acetophenone, 2,2-dimethoxy-2-phenylacetophenone, 2,2-diethoxy-2-phenylacetophenone, 1,1-dichloroacetophenone, 1-hydroxycyclohexyl phenyl ketone, 2-benzyl-2-dimethylamino-1-(4-morpholinophenyl)-butanone-1, 2-methyl-[4-(methylthio)phenyl]-2-morpholino-1-propane, and N,N-dimethylaminoacetophenone; anthraquinone compounds such as 2-methylanthraquinone, 2-ethylanthraquinone, 2-tert-butylanthraquinone, 1-chloroanthraquinone, 2-amylanthraquinone, and 2-aminoanthraquinone; thioxanthone compounds such as 2,4-dimethylthioxanthone, 2,4-diethylthioxanthone, 2-chlorothioxanthone, and 2,4-diisopropylthioxanthone; ketal compounds such as acetophenone dimethyl ketal and benzyl dimethyl ketal; benzophenone compounds such as benzophenone, methylbenzophenone, 4,4′-dichlorobenzophenone, 4,4′-bis(diethylamino)benzophenone, Michler's ketone, and 4-benzoyl-4′-methyldiphenyl sulfide; imidazole compounds such as 2-(o-chlorophenyl)-4,5-diphenylimidazole dimer, 2-(o-chlorophenyl)-4,5-di(m-methoxyphenyl)imidazole dimer, 2-(o-fluorophenyl)-4,5-diphenylimidazole dimer, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer, and 2-(2,4-dimethoxyphenyl)-4,5-diphenylimidazole dimer; acridine compounds such as 9-phenylacridine and 1,7-bis(9,9′-acridinyl)heptane; acylphosphine oxide compounds such as 2,4,6-trimethylbenzoyldiphenylphosphine oxide; oxime ester compounds such as 1,2-octanedione-1-[4-(phenylthio)phenyl]-2-(O-benzoyloxime), 1-[9-ethyl-6-(2-methylbenzoyl)-9H-carbazol-3-yl]ethanone 1-(0-acetyloxime), and 1-phenyl-1,2-propanedione-2-[0-(ethoxycarbonyl)oxime]; and tertiary amine compounds such as N,N-dimethylaminobenzoic acid ethyl ester, N,N-dimethylaminobenzoic acid isoamyl ester, pentyl-4-dimethylaminobenzoate, triethylamine, and triethanolamine.

The content of the component (C) in the photosensitive resin composition is not particularly limited, but may be 0.2% to 15% by mass, 0.4% to 5% by mass, or 0.6% to 1.5% by mass based on the total solid amount in the photosensitive resin composition.

### (Component (D): Photopolymerizable Compound)

The photosensitive resin composition according to the present embodiment contains a photopolymerizable compound as a component (D) from the viewpoint of enhancing the chemical resistance of the exposed portion and increasing the difference in developer resistance between the exposed portion and the unexposed portion. The component (D) is not particularly limited as long as it is a photopolymerizable compound that has a photopolymerizable functional group but does not have an acidic group. Examples of the photopolymerizable functional group include groups having an ethylenically unsaturated bond, such as a vinyl group, an allyl group, a propargyl group, a butenyl group, an ethynyl group, a phenylethynyl group, a maleimide group, a nadimide group, and a (meth)acryloyl group.

Examples of the component (D) include a photopolymerizable compound having one ethylenically unsaturated bond, a photopolymerizable compound having two ethylenically unsaturated bonds, and a photopolymerizable compound having three or more ethylenically unsaturated bonds.

Examples of the photopolymerizable compound having one ethylenically unsaturated bond include (meth)acrylic acid and a (meth)acrylic acid alkyl ester. Examples of the (meth)acrylic acid alkyl ester include (meth)acrylic acid methyl ester, (meth)acrylic acid ethyl ester, (meth)acrylic acid butyl ester, (meth)acrylic acid 2-ethylhexyl ester, and (meth)acrylic acid hydroxyethyl ester.

Examples of the photopolymerizable compound having two ethylenically unsaturated bond groups include polyethylene glycol di(meth)acrylate, trimethylolpropane di(meth)acrylate, polypropylene glycol di(meth)acrylate, 2,2-bis(4-(meth)acryloxypolyethoxypolypropoxyphenyl)propane, and bisphenol A diglycidyl ether di(meth)acrylate.

Examples of the photopolymerizable compound having three or more ethylenically unsaturated bonds include (meth)acrylate compounds having a skeleton derived from trimethylolpropane, such as trimethylolpropane tri(meth)acrylate; (meth)acrylate compounds having a skeleton derived from tetramethylolmethane, such as tetramethylolmethane tri(meth)acrylate and tetramethylolmethane tetra(meth)acrylate; (meth)acrylate compounds having a skeleton derived from pentaerythritol, such as pentaerythritol tri(meth)acrylate and pentaerythritol tetra(meth)acrylate; (meth)acrylate compounds having a skeleton derived from dipentaerythritol, such as dipentaerythritol penta(meth)acrylate and dipentaerythritol hexa(meth)acrylate; (meth)acrylate compounds having a skeleton derived from di(trimethylolpropane), such as ditrimethylolpropane tetra(meth)acrylate; and (meth)acrylate compounds having a skeleton derived from diglycerin.

Among these, from the viewpoint of enhancing the chemical resistance of the exposed portion and increasing the difference in developer resistance between the exposed portion and the unexposed portion, (meth)acrylate compounds having a skeleton derived from dipentaerythritol are preferred, and dipentaerythritol penta(meth)acrylate and dipentaerythritol hexa(meth)acrylate are more preferred.

The content of the component (D) may be 1% to 20% by mass, 2% to 15% by mass, or 3% to 10% by mass based on the total solid amount in the photosensitive resin composition.

### (Component (E): Elastomer)

As the photosensitive resin composition according to the present embodiment contains an elastomer as a component (E), the decrease in flexibility and adhesive strength caused by distortion (internal stress) inside the resin due to curing shrinkage of the component (A) can be suppressed. As the component (E) includes an acrylic elastomer, the heat resistance and impact resistance of a cured film to be formed from the photosensitive resin composition can be improved.

The acrylic elastomer can be synthesized by polymerizing a (meth)acrylic compound. Examples of the (meth)acrylic compound include (meth)acrylic acid, a (meth)acrylic acid ester, and an acrylonitrile.

Examples of the (meth)acrylic acid ester include methyl (meth)acrylate, (meth)acrylic acid, n-butyl (meth)acrylate, isobutyl (meth)acrylate, 2-ethylhexyl (meth)acrylate, 2-methoxyethyl (meth)acrylate, and 2-ethoxyethyl (meth)acrylate.

From the viewpoint of further improving the developability, the acrylic elastomer preferably has a carboxy group. The carboxy group can be introduced by polymerizing (meth)acrylic acid. The content of a structural unit based on (meth)acrylic acid in the acrylic resin may be 2% to 50% by mass, 5% to 30% by mass, 8% to 25% by mass, or 10% to 20% by mass. When the content of a structural unit based on (meth)acrylic acid is in the above range, the developability and resolution tend to be enhanced.

From the viewpoint of further improving impact resistance, the acrylic elastomer preferably has a n-butyl group. The n-butyl group can be introduced by polymerizing n-butyl (meth)acrylate. The content of a structural unit based on n-butyl (meth)acrylate in the acrylic elastomer may be 30% to 90% by mass, 40% to 85% by mass, 45% to 80% by mass, or 50% to 75% by mass. When the content of a structural unit based on n-butyl (meth)acrylate is in the above range, the resolution and impact resistance tend to be enhanced.

The weight average molecular weight (Mw) of the acrylic elastomer may be 1000 to 50000, 2000 to 40000, 3000 to 30000, 5000 to 20000, or 8000 to 18000. When the Mw of the acrylic elastomer is in the above range, the compatibility with the component (A) and the developability of unexposed portions tend to be excellent and the resolution tends to be even more excellent. The Mw of the acrylic elastomer can be measured by the GPC method described above.

The component (E) may further include an elastomer other than the acrylic elastomer. Examples of the component (E) other than the acrylic elastomer include a styrene-based elastomer, an olefin-based elastomer, a urethane-based elastomer, a polyester-based elastomer, a polyamide-based elastomer, and a silicone-based elastomer.

Examples of the styrene-based elastomer include a styrene-butadiene-styrene block copolymer, a styrene-isoprene-styrene block copolymer, a styrene-ethylene-butylene-styrene block copolymer, and a styrene-ethylene-propylene-styrene block copolymer. As a component constituting the styrene-based elastomer, in addition to styrene, styrene derivatives such as α-methylstyrene, 3-methylstyrene, 4-propylstyrene, and 4-cyclohexylstyrene can be used.

Examples of the olefin-based elastomer include an ethylene-propylene copolymer, an ethylene-α-olefin copolymer, an ethylene-α-olefin-non-conjugated diene copolymer, a propylene-α-olefin copolymer, a butene-α-olefin copolymer, an ethylene-propylene-diene copolymer, copolymers of non-conjugated dienes, such as dicyclopentadiene, 1,4-hexadiene, cyclooctadiene, methylene norbornene, ethylidene norbornene, butadiene, and isoprene, with α-olefins, epoxy-modified polybutadiene, and a carboxylic acid-modified butadiene-acrylonitrile copolymer.

The epoxy-modified polybutadiene preferably has a hydroxyl group at a molecular terminal, more preferably has a hydroxyl group at both molecular terminals, and still more preferably has a hydroxyl group only at both molecular terminals. The number of hydroxyl groups in the epoxy-modified polybutadiene may be 1 or more, preferably 1 to 5, more preferably 1 or 2, and still more preferably 2.

As the urethane-based elastomer, a compound composed of a hard segment consisting of a low molecular weight (short chain) diol and a diisocyanate and a soft segment consisting of a high molecular weight (long chain) diol and a diisocyanate can be used.

Examples of the short chain diol include ethylene glycol, propylene glycol, 1,4-butanediol, and bisphenol A. The number average molecular weight of the short chain diol is preferably 48 to 500.

Examples of the long chain diol include polypropylene glycol, polytetramethylene oxide, poly(1,4-butylene adipate), poly(ethylene-1,4-butylene adipate), polycaprolactone, poly(1,6-hexylene carbonate), and poly(1,6-hexylene-neopentylene adipate). The number average molecular weight of the long chain diol is preferably 500 to 10000.

As the polyester-based elastomer, a compound obtained by polycondensation of a dicarboxylic acid or a derivative thereof with a diol compound or a derivative thereof can be used.

Examples of the dicarboxylic acid include aromatic dicarboxylic acids such as terephthalic acid, isophthalic acid, and naphthalenedicarboxylic acid; aliphatic dicarboxylic acids having 2 to 20 carbon atoms, such as adipic acid, sebacic acid, and dodecanedicarboxylic acid; and alicyclic dicarboxylic acids such as cyclohexanedicarboxylic acid. The dicarboxylic acids can be used singly or in combination of two or more kinds thereof.

Examples of the diol compound include aliphatic diols such as ethylene glycol, 1,3-propanediol, 1,4-butanediol, 1,6-hexanediol, and 1,10-decanediol; alicyclic diols such as 1,4-cyclohexanediol; and aromatic diols such as bisphenol A, bis-(4-hydroxyphenyl)methane, bis-(4-hydroxy-3-methylphenyl)propane, and resorcinol.

As the polyester-based elastomer, a multiblock copolymer composed of an aromatic polyester (for example, polybutylene terephthalate) as a hard segment component and an aliphatic polyester (for example, polytetramethylene glycol) as a soft segment component can be used. There are various grades of polyester-based elastomers depending on the kind, ratio, and molecular weight of the hard and soft segments.

Polyamide-based elastomers are broadly classified into two types of a polyether block amide type and a polyether ester block amide type, in which a polyamide is used as the hard segment and a polyether or polyester is used as the soft segment. Examples of the polyamide include polyamide-6, polyamide-11, and polyamide-12. Examples of the polyether include polyoxyethylene glycol, polyoxypropylene glycol, and polytetramethylene glycol.

The silicone-based elastomer is a compound of which the main component is an organopolysiloxane. Examples of the organopolysiloxane include polydimethylsiloxane, polymethylphenylsiloxane, and polydiphenylsiloxane. The silicone-based elastomer may be a compound in which a part of an organopolysiloxane is modified with a vinyl group, an alkoxy group, or the like.

The content of the component (E) may be 1 to 40 parts by mass, 2 to 35 parts by mass, 3 to 30 parts by mass, or 4 to 15 parts by mass with respect to 100 parts by mass of the content of the component (A). The content of the component (E) with respect to 100 parts by mass of the content of the component (A) may be 5 parts by mass or more, 8 parts by mass or more, or 10 parts by mass or more, or may be 40 parts by mass or less, 35 parts by mass or less, 30 parts by mass or less, or 25 parts by mass or less. When the content of the component (E) is in the above range, the elastic modulus of the cured film in high temperature regions decreases and the unexposed portion is more likely to be eluted by the developer.

### (Component (F): Inorganic Filler)

The photosensitive resin composition according to the present embodiment may further contain an inorganic filler as a component (F). As the component (F) is contained, the adhesive strength and hardness of the permanent resist can be improved. The component (F) may be used singly or in combination of two or more kinds thereof.

Examples of the inorganic filler include silica, alumina, titania, tantalum oxide, zirconia, silicon nitride, barium titanate, barium carbonate, magnesium carbonate, aluminium hydroxide, magnesium hydroxide, lead titanate, lead zirconate titanate, lead lanthanum zirconate titanate, gallium oxide, spinel, mullite, cordierite, talc, aluminium titanate, yttria-containing zirconia, barium silicate, boron nitride, calcium carbonate, barium sulfate, calcium sulfate, zinc oxide, magnesium titanate, hydrotalcite, mica, calcined kaolin, and carbon.

The component (F) may contain silica from the viewpoint of improving the heat resistance of the permanent resist, and may contain barium sulfate or may contain silica and barium sulfate from the viewpoint of improving the heat resistance and adhesive strength of the permanent resist. From the viewpoint of improving the dispersibility of the inorganic filler, an inorganic filler that has undergone surface treatment with alumina or an organosilane compound in advance may be used.

From the viewpoint of resolution, the average particle size of the inorganic filler may be 0.01 μm to 5.0 μm, 0.05 μm to 3.0 μm, 0.1 μm to 2.0 μm, or 0.15 μm to 1.0 μm.

The average particle size of the component (F) is the average particle size of the inorganic filler in a state of being dispersed in the photosensitive resin composition, and is a value obtained by performing measurement as follows. First, the photosensitive resin composition is diluted with methyl ethyl ketone 1000 times, and the particles dispersed in the solvent are measured at a refractive index of 1.38 using a submicron particle analyzer (manufactured by Beckman Coulter, Inc., trade name: N5) in conformity with the international standard ISO 13321, and the particle size at an integrated value of 50% (volume basis) in the particle size distribution is taken as the average particle size.

The content of the component (F) may be 10% to 70% by mass, 15% to 60% by mass, or 20% to 50% by mass based on the total solid amount in the photosensitive resin composition. When the content of the component (E) is in the above range, the low thermal expansion coefficient, heat resistance, and film strength can be further improved.

The content of silica in a case of using silica as the component (F) may be 5% to 60% by mass, 10% to 40% by mass, or 15% to 30% by mass based on the total solid amount in the photosensitive resin composition. The content of barium sulfate in a case of using barium sulfate as the component (F) may be 5% to 30% by mass, 8% to 25% by mass, or 10% to 20% by mass based on the total solid amount in the photosensitive resin composition. When the contents of silica and barium sulfate are in the above ranges, there is a tendency that low thermal expansion coefficient, solder heat resistance, and adhesive strength are excellent.

### (Component (G): Pigment)

The photosensitive resin composition according to the present embodiment may further contain a pigment as a component (G) from the viewpoint of improving the distinguishability or appearance of the production apparatus. As the component (G), a colorant that produces a desired color when the wiring (conductor pattern) is concealed can be used. The component (G) may be used singly or in combination of two or more kinds thereof.

Examples of the component (G) include phthalocyanine blue, phthalocyanine green, iodine green, diazo yellow, crystal violet, titanium oxide, carbon black, and naphthalene black.

The content of the component (G) may be 0.01% to 5.0% by mass, 0.03% to 3.0% by mass, or 0.05% to 2.0% by mass based on the total solid amount in the photosensitive resin composition from the viewpoints of easily distinguishing the production apparatus and further concealing the wiring.

### (Component (H): Ion Trapping Agent)

The photosensitive resin composition according to the present embodiment may further contain an ion trapping agent as a component (H) from the viewpoint of improving the resist shape, close contact properties, fluidity, and reliability. The component (H) is not particularly limited as long as it is capable of trapping ions in the ion trapping agent and has the function of trapping at least either of a cation or an anion.

The ions to be trapped in the present embodiment are ions that are incorporated into the composition that reacts by the irradiation with light, an electron beam, or the like and thus undergoes a change in solubility in the solvent, for example, a sodium ion (Na⁺), a chloride ion (Cl⁻), a bromine ion (Br⁻), and a copper ion (Cu⁺, Cu²⁺). By trapping these ions, electric insulation, resistance to electrolytic corrosion, and the like are improved.

The component (H) is preferably an ion trapping agent having at least one selected from the group consisting of Zr (zirconium), Bi (bismuth), Mg (magnesium), and Al (aluminium). The component (H) may be used singly or in combination of two or more kinds thereof.

Examples of the component (H) include a cation trapping agent that traps cations, an anion trapping agent that traps anions, and an amphoteric ion trapping agent that traps both cations and anions.

Examples of the cation trapping agent include inorganic ion exchangers of metal oxides such as zirconium phosphate, zirconium tungstate, zirconium molybdate, zirconium tungstate, zirconium antimonate, zirconium selenate, zirconium tellurite, zirconium silicate, zirconium phosphosilicate, and zirconium polyphosphate.

Examples of the anion trapping agent include inorganic ion exchangers such as bismuth oxide hydrate and hydrotalcites.

Examples of the amphoteric ion trapping agent include inorganic ion exchangers of metal oxide hydrates such as aluminium oxide hydrate and zirconium oxide hydrate. As the amphoteric ion trapping agent, IXE-1320 (Mg, Al-containing compound), IXE-600 (Bi-containing compound), IXE-633 (Bi-containing compound), IXE-680 (Bi-containing compound), IXE-6107 (Zr, Bi-containing compound), IXE-6136 (Zr, Bi-containing compound), IXEPLAS-A1 (Zr, Mg, Al-containing compound), IXEPLAS-A2 (Zr, Mg, Al-containing compound), IXEPLAS-B1 (Zr, Bi-containing compound) that are manufactured by TOAGOSEI CO., LTD., and the like are commercially available.

As the component (H), those in the form of particles can be used, and from the viewpoint of improving the insulation properties, the average particle size of the component (H) may be 5 μm or less, 3 μm or less, or 2 μm or less or may be 0.1 μm or more. The average particle size of the component (H) is the particle size of particles in a state of being dispersed in the photosensitive resin composition, and can be measured by the same method as that for measuring the average particle size of the component (F).

In a case where the photosensitive resin composition contains the component (H), the content of the component (H) is not particularly limited, but may be 0.05% to 10% by mass, 0.1% to 5% by mass, or 0.2% to 1% by mass based on the total solid amount in the photosensitive resin composition from the viewpoint of improving electric insulation and resistance to electrolytic corrosion.

### (Component (I): Silane Coupling Agent)

The photosensitive resin composition according to the present embodiment may further contain a silane coupling agent as a component (I). As the component (I), a known silane coupling agent can be used. The component (I) can improve the adhesive properties of an electronic component to a substrate, and is particularly effective in a case where the substrate is a substrate containing silicon (for example, a glass substrate, a silicon wafer, or an epoxy resin-impregnated glass cloth substrate).

Examples of the silane coupling agent include alkoxysilanes such as methyltrimethoxysilane, methyltriethoxysilane, phenyltrimethoxysilane, and phenyltriethoxysilane; (meth)acryloyl group-containing alkoxysilanes such as (meth)acryloxypropyltrimethoxysilane and (meth)acryloxypropylmethyldimethoxysilane; amine-based alkoxysilanes such as γ-aminopropyltrimethoxysilane, γ-aminopropyltriethoxysilane, N-phenyl-3-aminopropyltrimethoxysilane, and 3-triethoxysilyl-N-(1,3-dimethylbutylidene)propylamine; glycidoxy group-containing alkoxysilanes such as γ-glycidoxypropyltrimethoxysilane, γ-glycidoxypropyltriethoxysilane, glycidoxypropylmethyldiethoxysilane, and glycidoxypropylmethyldiisopropenoxysilane; alicyclic epoxy group-containing alkoxysilanes such as 2-(3,4-epoxycyclohexyl)ethyltrimethoxysilane; ureido group-containing alkoxysilanes such as 3-ureidopropyltriethoxysilane; mercapto group-containing alkoxysilanes such as 3-mercaptopropyltrimethoxysilane and 3-mercaptopropylmethyldimethoxysilane; carbamate group-containing alkoxysilanes such as triethoxysilylpropylethyl carbamate; and polybasic acid anhydride group-containing alkoxysilanes such as 3-(triethoxysilyl)propylsuccinic anhydride. The silane coupling agents may be used singly or in combination of two or more kinds thereof.

From the viewpoint of further improving adhesive properties, the component (I) preferably includes a silane coupling agent having a (meth)acryloyl group. As a silane coupling agent having a (meth)acryloyl group is used, the heat resistance of the permanent resist can be maintained and bleeding from the composition can be suppressed. In this specification, a silane coupling agent having a (meth)acryloyl group is not included in the component (D).

Examples of commercially available products of the silane coupling agent having a (meth)acryloyl group include KBM-502, KBM-503, KBE-502, KBE-503, and KBM-5103 (manufactured by Shin-Etsu Chemical Co., Ltd.).

The content of the component (I) may be 0.1% to 10% by mass, 0.5% to 5% by mass, or 1% to 3% by mass based on the total solid amount in the photosensitive resin composition. When the content of the component (I) is in the above range, there is a tendency that close contact properties to a silicon wafer are excellent and resolution is excellent.

### (Curing Agent)

The photosensitive resin composition according to the present embodiment may contain a curing agent for the purpose of further improving the properties of the cured film, such as heat resistance, close contact properties, and chemical resistance. The curing agent may be used singly or in combination of two or more kinds thereof.

Examples of the curing agent include an imidazole compound, a guanamine compound, an amine compound, and a triazine compound. Examples of the imidazole compound include 2-methylimidazole, 2-ethyl-4-methylimidazole, 1-benzyl-2-methylimidazole, 2-phenylimidazole, and 2-phenyl-4-methyl-5-hydroxymethylimidazole. Examples of the guanamine compound include acetoguanamine and benzoguanamine. Examples of the amine compound include diaminodiphenylmethane, m-phenylenediamine, m-xylylenediamine, diaminodiphenylsulfone, dicyandiamide, urea, urea derivatives, melamine, and polybasic hydrazides. Examples of the triazine compound include ethyldiamino-s-triazine, 2,4-diamino-s-triazine, and 2,4-diamino-6-xylyl-s-triazine.

The content of the curing agent may be 0.01% to 20% by mass, 0.05% to 10% by mass, or 0.1% to 5% by mass based on the total solid amount in the photosensitive resin composition from the viewpoint of improving reliability of the cured film.

### (Other Components)

The photosensitive resin composition according to the present embodiment may further contain various additives, if necessary.

Examples of the additives include polymerization inhibitors such as hydroquinone, methylhydroquinone, hydroquinone monomethyl ether, catechol, and pyrogallol; thickeners such as Bentone and montmorillonite; silicone-based, fluorine-based and vinyl resin-based defoamers; and flame retardants such as a brominated epoxy compound, an acid-modified brominated epoxy compound, an antimony compound, a phosphate compound, an aromatic condensed phosphate ester, and a halogen-containing condensed phosphate ester.

### (Solvent)

As the photosensitive resin composition according to the present embodiment contains a solvent for dissolving and dispersing each component, application onto a substrate is facilitated and a coating film having a uniform thickness can be formed.

Examples of the solvent include ketones such as methyl ethyl ketone and cyclohexanone; aromatic hydrocarbons such as toluene, xylene, and tetramethylbenzene; glycol ethers such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; esters such as ethyl acetate, butyl acetate, butyl cellosolve acetate, and carbitol acetate; aliphatic hydrocarbons such as octane and decane; and petroleum-based solvents such as petroleum ether, petroleum naphtha, hydrogenated petroleum naphtha, and solvent naphtha. The solvents may be used singly or in combination of two or more kinds thereof.

The amount of the solvent is not particularly limited, but the proportion of the solvent in the photosensitive resin composition may be 10% to 50% by mass, 20% to 40% by mass, or 25% to 35% by mass.

The photosensitive resin composition according to the present embodiment can be prepared by uniformly mixing the respective components described above using a roll mill, a bead mill, or the like.

### [Photosensitive Element]

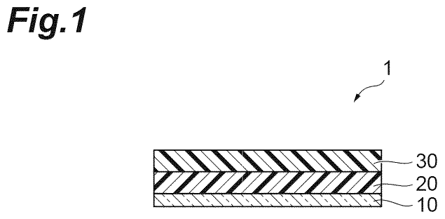

The photosensitive element according to the present embodiment includes a support film and a photosensitive layer containing the photosensitive resin composition described above. FIG. 1 is a cross-sectional view schematically illustrating the photosensitive element according to the present embodiment. As illustrated in FIG. 1, a photosensitive element 1 includes a support film 10 and a photosensitive layer 20 formed on the support film 10.

The photosensitive element 1 can be produced by applying the photosensitive resin composition according to the present embodiment onto the support film 10 by a known method such as reverse roll coating, gravure roll coating, comma coating, or curtain coating and then drying the coating film to form the photosensitive layer 20.

Examples of the support film include polyester films such as polyethylene terephthalate and polybutylene terephthalate; and polyolefin films such as polypropylene and polyethylene. The thickness of the support film may be, for example, 5 μm to 100 μm. The thickness of the photosensitive layer may be, for example, 5 μm to 50 μm, 5 μm to 40 μm, or 10 μm to 30 μm. The surface roughness of the support film is not particularly limited, but the arithmetic mean roughness (Ra) may be 1000 nm or less, 500 nm or less, or 250 nm or less.

For drying of the coating film, hot air drying or drying using far infrared rays or near infrared rays can be adopted. The drying temperature may be 60° C. to 120° C., 70° C. to 110° C., or 80° C. to 100° C. The drying time may be 1 minute to 60 minutes, 2 minutes to 30 minutes, or 5 minutes to 20 minutes.

A protective film 30 that covers the photosensitive layer 20 may further be provided on the photosensitive layer 20. In the photosensitive element 1, the protective film 30 can also be laminated on the surface of the photosensitive layer 20 opposite to the surface in contact with the support film 10. As the protective film 30, for example, a polymer film such as polyethylene or polypropylene may be used.

### [Printed Wiring Board]

The printed wiring board according to the present embodiment includes a permanent resist containing a cured product of the photosensitive resin composition according to the present embodiment.

The method for producing a printed wiring board according to the present embodiment includes a step of forming a photosensitive layer on a substrate using the photosensitive resin composition or photosensitive element described above; a step of exposing and developing the photosensitive layer to form a resist pattern; and a step of curing the resist pattern to form a permanent resist. Hereinafter, an example of each step will be described.

First, a substrate such as a copper-clad laminate is prepared, and a photosensitive layer is formed on the substrate. The photosensitive layer may be formed by applying a photosensitive resin composition onto a substrate and performing drying. Examples of the method for applying a photosensitive resin composition include a screen printing method, a spraying method, a roll coating method, a curtain coating method, and an electrostatic coating method. The drying temperature may be 60° C. to 120° C., 70° C. to 110° C., or 80° C. to 100° C. The drying time may be 1 minute to 7 minutes, 1 minute to 6 minutes, or 2 minutes to 5 minutes. The thickness of the photosensitive layer is preferably 5 μm or more, and may be 10 μm to 200 μm, 15 μm to 150 μm, 20 μm to 100 μm, or 23 μm to 50 μm.

The photosensitive layer may be formed on the substrate by peeling off the protective film from the photosensitive element and laminating the photosensitive layer. Examples of the method for laminating a photosensitive layer include a method in which thermal lamination is performed using a laminator.

Next, a negative film is brought into contact with the photosensitive layer directly or via a support film, and the photosensitive layer is exposed by being irradiated with actinic light. Examples of the actinic light include electron beams, ultraviolet light, and X-rays, and ultraviolet light is preferred. As the light source, a low pressure mercury lamp, a high pressure mercury lamp, an ultra-high pressure mercury lamp, a halogen lamp, and the like can be used. The exposure may be 10 mJ/cm² to 2000 mJ/cm², 100 mJ/cm² to 1500 mJ/cm², or 300 mJ/cm² to 1000 mJ/cm².

After exposure, the unexposed portions are removed with a developer to form a resist pattern. Examples of the developing method include a dipping method and a spraying method. As the developer, for example, an aqueous alkali solution of potassium hydroxide, sodium hydroxide, sodium carbonate, potassium carbonate, tetramethylammonium hydroxide or the like can be used.

The resist pattern is subjected to at least one of post-exposure or post-heating, whereby a patterned cured film (permanent resist) can be formed. The exposure in post-exposure may be 100 mJ/cm² to 5000 mJ/cm², 500 mJ/cm² to 2000 mJ/cm², or 700 mJ/cm² to 1500 J/cm². The heating temperature for post-heating may be 100° C. to 200° C., 120° C. to 180° C., or 135° C. to 165° C. The heating time for post-heating may be 5 minutes to 12 hours, 10 minutes to 6 hours, or 30 minutes to 2 hours.

The permanent resist according to the present embodiment can be used as an interlayer insulating layer or a surface protection layer of a semiconductor element. A semiconductor element having an interlayer insulating layer or surface protection layer formed from a cured film of the photosensitive resin composition described above, and an electronic device including the semiconductor element can be produced. The semiconductor element may be, for example, a memory, a package, or the like having a multilayer wiring structure, a rewiring structure, or the like. Examples of electronic devices include mobile phones, smartphones, tablet terminals, personal computers, and hard disk suspensions. It is possible to provide a semiconductor element and an electronic device that are excellent in reliability by including a patterned cured film that is formed from the photosensitive resin composition according to the present embodiment.

### EXAMPLES

Hereinafter, the present disclosure will be described in more detail with reference to Examples, but the present disclosure is not limited to these Examples.

### Synthesis Example 1

While being stirred at 90° C., 350 parts by mass of bisphenol F novolac type epoxy resin (manufactured by DIC Corporation, trade name “EXA-7376”, a bisphenol F novolac type epoxy resin having a structural unit represented by Formula (II) where Y³ and Y⁴ are glycidyl groups and R¹² is a hydrogen atom, epoxy equivalent: 186), 70 parts by mass of acrylic acid, 0.5 parts by mass of methylhydroquinone, and 120 parts by mass of carbitol acetate were mixed. The liquid mixture was cooled to 60° C., 2 parts by mass of triphenylphosphine was added, and the mixture was reacted at 100° C. until the acid value of the solution became 1 mgKOH/g or less. To the reaction solution, 98 parts by mass of tetrahydrophthalic anhydride (THPAC) and 85 parts by mass of carbitol acetate were added, and the mixture was reacted at 80° C. for 6 hours. Thereafter, the reaction solution was cooled to room temperature to obtain a solution of acid-modified epoxy acrylate (A-1) (solid concentration: 73% by mass) as a component (A).

### Synthesis Example 2

Into a 100 mL three-neck flask equipped with a stirrer, a nitrogen introducing tube, and a thermometer, 70 g of ethyl lactate, 13.4 g of methyl acrylate, 22.5 g of n-butyl acrylate, 2.0 g of acrylic acid, and 3.0 g of azobisisobutyronitrile were added, and then while stirring was performed at about 160 rpm and room temperature, nitrogen gas was allowed to flow at a flow rate of 400 mL/min for 30 minutes to remove dissolved oxygen in the flask. Thereafter, the flow of nitrogen gas was stopped, the flask was sealed, and the temperature was raised to 65° C. in a constant temperature water bath for about 25 minutes. The mixture was kept at the same temperature for 10 hours to conduct the polymerization reaction, whereby an acrylic elastomer (E-1) was obtained. The Mw of E-1 was about 10000.

### Synthesis Example 3

A polymerization reaction was conducted in the same manner as in the synthesis of E-1 except that 70 g of ethyl lactate, 2.8 g of methyl acrylate, 13.3 g of n-butyl acrylate, 2.4 g of acrylic acid, and 1.0 g of azobisisobutyronitrile were added to obtain an acrylic elastomer (E-2). The Mw of E-2 was about 15000.

The following materials were prepared as components (A) to (I).
A-1: Acid-modified epoxy acrylate (A-1) of Synthesis Example 1
B-1: Bisphenol F type epoxy resin (manufactured by NIPPON STEEL Chemical & Material Co., Ltd., trade name “YDF-8170C”, average molecular weight: 310 to 330, epoxy equivalent: 155 to 165)
B-2: Bisphenol A type epoxy resin (manufactured by NIPPON STEEL Chemical & Material Co., Ltd., trade name “YD-8125”, average molecular weight: 336 to 356, epoxy equivalent: 168 to 178)
B-3: Bisphenol A type epoxy resin (manufactured by Mitsubishi Chemical Corporation, trade name “jER828”, average molecular weight: 368 to 388, epoxy equivalent: 184 to 194)
B-4: Phenol novolac type epoxy resin (manufactured by Nippon Kayaku Co., Ltd., trade name “RE-306”, average molecular weight: 400, epoxy equivalent: 170 to 181)
C-1: 2-Methyl-[4-(methylthio)phenyl]morpholino-1-propanone (manufactured by IGM Resins B.V., trade name “Omirad 907”)
C-2: 2,4-Diethylthioxanthone (manufactured by Nippon Kayaku Co., Ltd., trade name “DETX-S”)
C-3: 4,4′-Bis(diethylamino)benzophenone (EAB)
C-4: Ethanone, 1-[9-ethyl-6-(2-methylbenzoyl)-9H-carbazol-3-yl]-, 1-(0-acetyloxime) (manufactured by BASF Japan Ltd., trade name “Irgacure OXE02”)
D-1: Dipentaerythritol hexaacrylate (manufactured by Nippon Kayaku Co., Ltd., trade name “DPHA”)
E-1: Acrylic elastomer (E-1) of Synthesis Example 2
E-2: Acrylic elastomer (E-2) of Synthesis Example 3
F-1: Silica (manufactured by Denka Company Limited, trade name “SFP20M”, average particle size: 0.3 μm)
F-2: Barium sulfate (manufactured by SAKAI CHEMICAL INDUSTRY CO., LTD., trade name “B-34”, average particle size: 0.3 μm)
G-1: Phthalocyanine-based pigment (manufactured by SANYO COLOR WORKS, Ltd.)
H-1: Zr, Mg, Al-Containing amphoteric ion trapping agent (manufactured by TOAGOSEI CO., LTD., trade name “IXEPLAS-A2”, average particle size: 0.2 μm, content of Zr compound: 20% to 30% by mass)
I-1: 3-Methacryloxypropyltriethoxysilane (manufactured by Shin-Etsu Chemical Co., Ltd., trade name “KBM-503”)

### [Photosensitive Resin Composition]

The respective components were blended in the amounts (parts by mass, in terms of solid) shown in Table 1 or Table 2, and kneaded using a three-roll mill. Thereafter, carbitol acetate was added so that the solid concentration became 70% by mass, thereby preparing a photosensitive resin composition.

### [Photosensitive Element]

As a support film, a polyethylene terephthalate film having a thickness of 25 μm (manufactured by Toyobo Film Solutions Co., Ltd., trade name “G2-25”) was prepared. A solution obtained by diluting the photosensitive resin composition with methyl ethyl ketone was applied onto the support film so as to have a thickness after drying of 25 μm, and dried at 75° C. for 30 minutes using a hot air convection dryer to form a photosensitive layer. Next, a polyethylene film (manufactured by TAMAPOLY CO., LTD., trade name “NF-15”) as a protective film was pasted to the surface of the photosensitive layer opposite to the surface in contact with the support film, thereby obtaining a photosensitive element.

### (Resolution)

A copper-clad laminated substrate having a thickness of 0.6 mm (manufactured by Showa Denko Materials Co., Ltd., trade name “MCL-E-67”) was prepared. While peeling off and removing the protective film from the photosensitive element, the photosensitive layer was laminated on the copper-clad laminated substrate at a pressure for pressure bonding of 0.4 MPa, a press hot plate temperature of 80° C., a vacuuming time of 25 seconds, and a lamination press time of 25 seconds using a press-type vacuum laminator (manufactured by MEIKI CO., LTD., trade name “MVLP-500”), thereby obtaining a laminate. Next, a negative mask having an opening pattern of a predetermined size (opening diameter size: 30, 40, 50, 60, 70, 80, 90, 100, 110, 120, 150, or 200 μm) was brought into close contact with the support film of the laminate, and the photosensitive layer was exposed at an exposure that resulted in 13 complete curing steps on a step tablet (manufactured by Showa Denko Materials Co., Ltd.) using an ultraviolet exposure system (manufactured by Oak Co., Ltd., trade name “EXM-1201”). Thereafter, the support film was peeled off from the photosensitive layer, and spray development was performed at a pressure of 1.765×10⁵ Pa for 60 seconds using a 1% by mass aqueous solution of sodium carbonate to dissolve and develop the unexposed portions. Next, the developed photosensitive layer was exposed at an exposure of 2000 mJ/cm² using an ultraviolet exposure system, and then heated at 170° C. for 1 hour to fabricate a test piece having a cured film on which an opening pattern of a predetermined size was formed on a copper-clad laminated substrate. The test piece was observed under an optical microscope and evaluated according to the following criteria.
A: The minimum opening diameter size was 30 μm or less.
B: The minimum opening diameter size was more than 30 μm and less than 50 μm.
C: The minimum opening diameter size was more than 50 μm.

### (Resist Pattern Shape)

The test piece was cast with an embedding resin (trade name “jER828” manufactured by Mitsubishi Chemical Corporation and triethylenetetramine were used as an epoxy resin and a curing agent, respectively), sufficiently cured, and then polished using a polishing machine (manufactured by Refine Tec Ltd., trade name “Refine Polisher”) to cut out a cross section of the opening pattern of the cured film. The obtained cross section of the opening pattern was observed under a metallurgical microscope and evaluated according to the following criteria.
A: Undercut or missing of the resist upper part was not observed, and the linearity of the pattern contour was favorable.
B: Undercut or missing of the resist upper part was observed, or the linearity of the pattern contour was poor.

### (Thermal Shock Resistance)

The test piece fabricated in the evaluation of resolution was subjected to a temperature cycle test in which one cycle consisted of 30 minutes at −65° C. and 30 minutes at 150° C., and the test piece was observed visually and under an optical microscope at the time points of 1000 cycles and 2000 cycles and evaluated according to the following criteria.
A: Generation of cracks was not observed after 2000 cycles.
B: Generation of cracks was not observed after 1000 cycles, but generation of cracks was observed after 2000 cycles.
C: Generation of cracks was observed after 1000 cycles.

### (Heat Resistance)

The test piece fabricated in the evaluation of resolution was placed in an environment of 150° C., and the test piece was observed visually and under an optical microscope after 1000 hours and 2000 hours and evaluated according to the following criteria.
A: Generation of cracks was not observed after 2000 hours.
B: Generation of cracks was not observed after 1000 hours, but generation of cracks was observed after 2000 hours.
C: Generation of cracks was observed after 1000 hours.

### (Adhesive Properties)

A laminate having a photosensitive layer was fabricated in the same manner as the laminate fabricated in the evaluation of resolution except that the copper-clad laminated substrate was replaced with a 6-inch silicon wafer (manufactured by ELECTRONICS AND MATERIALS CORPORATION LIMITED). The entire surface of the laminate was exposed at 500 mJ/cm² using an i-line exposure system (manufactured by Ushio Inc., trade name “UX-2240SM-XJ-01”). Next, the support film was peeled off from the photosensitive layer, and the photosensitive layer was further exposed at an exposure of 2000 mJ/cm² using an ultraviolet exposure system and then heated at 170° C. for 1 hour to form a cured film of the photosensitive resin composition on a silicon wafer. Thereafter, an Al stud pin with epoxy adhesive (manufactured by PHOTOTECHNICA CORPORATION, trade name “P/N901106”, adhesive portion diameter: 2.7 mm) was placed perpendicularly on the cured film, and heating was performed at 150° C. for 1 hour to obtain a test piece. The stud pin on the test piece was fixed to the chuck of a thin film adhesive strength measuring apparatus (manufactured by PHOTOTECHNICA CORPORATION), and a force was applied perpendicularly to the cured film. The adhesive properties of the cured film to the silicon wafer were evaluated according to the following criteria.
A: Peeling did not occur at the interface between the cured film and the silicon wafer, but the epoxy adhesive underwent cohesive failure.
B: Peeling occurred at the interface between the cured film and the silicon wafer.

TABLE 1

| | | Example | | | | | |
|---|---|---|---|---|---|---|---|
| | | 1 | 2 | 3 | 4 | 5 | 6 |
| A | A-1 | 35 | 35 | 35 | 35 | 35 | 35 |
| B | B-1 | 13.1 | — | — | — | — | — |
| | B-2 | — | 13.1 | 13.1 | 8.7 | 5 | 13.1 |
| | B-3 | — | — | — | — | — | — |
| | B-4 | — | — | — | 4.4 | 8.1 | — |
| C | C-1 | 0.9 | 0.9 | 0.9 | 0.9 | 0.9 | 0.9 |
| | C-2 | 0.1 | 0.1 | 0.1 | 0.1 | 0.1 | 0.1 |
| | C-3 | 0.1 | 0.1 | 0.1 | 0.1 | 0.1 | 0.1 |
| | C-4 | 0.1 | 0.1 | 0.1 | 0.1 | 0.1 | 0.1 |
| D | D-1 | 5.2 | 5.2 | 5.2 | 5.2 | 5.2 | 5.2 |
| E | E-1 | 8 | 8 | — | 8 | 8 | 8 |
| | E-2 | — | — | 8 | — | — | — |
| F | F-1 | 17.5 | 17.5 | 17.5 | 17.5 | 17.5 | 17.5 |
| | F-2 | 13.1 | 13.1 | 13.1 | 13.1 | 13.1 | 13.1 |
| G | G-1 | 1.3 | 1.3 | 1.3 | 1.3 | 1.3 | 1.3 |
| H | H-1 | 0.4 | 0.4 | 0.4 | 0.4 | 0.4 | 0.4 |
| I | I-1 | 2 | 2 | 2 | 2 | 2 | — |

| | | | | | | |
|---|---|---|---|---|---|---|
| Resolution | A | A | A | A | A | A |
| Resist pattern shape | A | A | A | A | A | A |
| Thermal shock resistance | A | A | A | A | A | A |
| Heat resistance | A | A | A | A | A | A |
| Adhesive properties | A | A | A | A | A | B |

TABLE 2

| | | Comparative Example | | | | |
|---|---|---|---|---|---|---|
| | | 1 | 2 | 3 | 4 | 5 |
| A | A-1 | 35 | 35 | 35 | 35 | 35 |
| B | B-1 | — | — | — | — | — |
| | B-2 | 13.1 | — | — | — | — |
| | B-3 | — | 13.1 | — | 8.7 | 8.7 |
| | B-4 | — | — | 13.1 | 4.4 | 4.4 |
| C | C-1 | 0.9 | 0.9 | 0.9 | 0.9 | 0.9 |
| | C-2 | 0.1 | 0.1 | 0.1 | 0.1 | 0.1 |
| | C-3 | 0.1 | 0.1 | 0.1 | 0.1 | 0.1 |
| | C-4 | 0.1 | 0.1 | 0.1 | 0.1 | 0.1 |
| D | D-1 | 5.2 | 5.2 | 5.2 | 5.2 | 5.2 |
| E | E-1 | — | 8 | 8 | — | 8 |
| | E-2 | — | — | — | — | — |
| F | F-1 | 17.5 | 17.5 | 17.5 | 17.5 | 17.5 |
| | F-2 | 13.1 | 13.1 | 13.1 | 13.1 | 13.1 |
| G | G-1 | 1.3 | 1.3 | 1.3 | 1.3 | 1.3 |
| H | H-1 | 0.4 | 0.4 | 0.4 | 0.4 | 0.4 |
| I | I-1 | 2 | 2 | 2 | 2 | — |

| | | | | | |
|---|---|---|---|---|---|
| Resolution | A | B | B | A | A |
| Resist pattern shape | A | B | B | A | A |
| Thermal shock resistance | B | C | A | C | B |
| Heat resistance | B | C | B | C | B |
| Adhesive properties | A | A | A | A | B |

### REFERENCE SIGNS LIST

1: photosensitive element, 10: support film, 20: photosensitive layer, and 30: protective film.

1. A photosensitive resin composition comprising: (A) an acid-modified vinyl group-containing resin; (B) a thermosetting resin; (C) a photopolymerization initiator; (D) a photopolymerizable compound; and (E) an elastomer,
wherein the thermosetting resin includes a bisphenol type epoxy compound having an average molecular weight of 360 or less, and
the elastomer includes an acrylic elastomer.

2. The photosensitive resin composition according to claim 1, wherein a content of the thermosetting resin is 5% to 25% by mass based on a total solid amount in the photosensitive resin composition.

3. The photosensitive resin composition according to claim 1, wherein the acrylic elastomer has a carboxy group.

4. The photosensitive resin composition according to claim 3, wherein the acrylic elastomer further has a n-butyl group.

5. The photosensitive resin composition according to claim 1, wherein the acrylic elastomer has a weight average molecular weight of 5000 to 20000.

6. The photosensitive resin composition according to claim 1, further comprising (I) a silane coupling agent.

7. The photosensitive resin composition according to claim 1, further comprising (F) an inorganic filler.

8. A photosensitive element comprising: a support film; and a photosensitive layer formed on the support film,
wherein the photosensitive layer contains the photosensitive resin composition according to claim 1.

9. A printed wiring board comprising a permanent resist containing a cured product of the photosensitive resin composition according to claim 1.

10. A method for producing a printed wiring board, the method comprising:
a step of forming a photosensitive layer on a substrate using the photosensitive resin composition according to claim 1;
a step of exposing and developing the photosensitive layer to form a resist pattern; and
a step of curing the resist pattern to form a permanent resist.

11. A method for producing a printed wiring board, the method comprising:
a step of forming a photosensitive layer on a substrate using the photosensitive element according to claim 8;
a step of exposing and developing the photosensitive layer to form a resist pattern; and
a step of curing the resist pattern to form a permanent resist.
